(19) United States
(12) Patent Application Publication
(10) Pub. No.: US 2026/0369860 A1
(43) Pub. Date: Nov. 19, 2026

(54) TUNABLE HYBRID COUPLER

(71) Applicant: TEXAS INSTRUMENTS INCORPORATED, Dallas, TX (US)

(72) Inventors: Zheng Liu, Richardson, TX (US); Siraj Akhtar, Richardson, TX (US)

(21) Appl. No.: 19/209,223

(22) Filed: May 15, 2025

(51) Int. Cl. H01P 5/19; H03F 3/19

(52) U.S. Cl. CPC H01P 5/19; H03F 3/19; H03F 2200/451

(57) ABSTRACT

Described is an apparatus including a hybrid coupler circuit having a first terminal, a second terminal, a third terminal, and a fourth terminal, and one or more control inputs. In an example, the hybrid coupler circuit is coupled to a bias network or a passive impedance termination. In an example, the hybrid coupler is configurable to provide signal coupling between the third terminal and each of first and second terminals; and responsive to one or more control signals at the one or more control inputs, configure at least one of a phase offset or an amplitude offset between signals at the first and second terminals.

### BACKGROUND

A hybrid coupler is a four-port radio frequency (RF) circuit that splits or combines signals in a balanced and symmetrical manner, while providing high isolation between the ports. For example, a hybrid coupler can split an input signal into two output signals having a specific phase offset, such as at 90 degrees or 180 degrees phase offset. Also, a hybrid coupler can generate an output signal by combining/summing input signals having the specific phase offset. Hybrid couplers are widely used in microwave, RF, and communication systems.

### SUMMARY

Some examples describe an apparatus comprising: a hybrid coupler circuit having a first terminal, a second terminal, a third terminal, and a fourth terminal, and one or more control inputs, the hybrid coupler circuit coupled to a bias network or a passive impedance termination and configurable to: provide signal coupling between the third terminal and each of first and second terminals; and responsive to one or more control signals at the one or more control inputs, configure at least one of a phase offset or an amplitude offset between signals at the first and second terminals.

Some examples describe an apparatus comprising: a first amplifier circuit; a second amplifier circuit; a hybrid coupler circuit having a first terminal, a second terminal, a third terminal, and a fourth terminal, the first terminal coupled to the first amplifier circuit, the second terminal coupled to the second amplifier circuit, in which the hybrid coupler circuit has at least one of a configurable amplitude offset or a configurable phase offset between signals at the first and second terminals, and the third terminal coupled to an input or an output of a third amplifier circuit; and a bias network or a passive impedance termination coupled to the fourth terminal.

Some examples describe an integrated circuit comprising: a first amplifier circuit; a second amplifier circuit; and a hybrid coupler circuit having a first terminal, a second terminal, a third terminal, a fourth terminal, the first terminal coupled to the first amplifier circuit, the second terminal coupled to the second amplifier circuit, in which the hybrid coupler circuit has at least one of a configurable amplitude offset or a configurable phase offset between the first and second terminals, wherein a conductor coupled between the first and second terminals is in a metallization structure of the integrated circuit.

### BRIEF DESCRIPTION OF THE DRAWINGS

The examples will be understood more fully from the detailed description given below and from the accompanying drawings, which, however, should not be taken to limit the disclosure to the specific examples, but are for explanation and understanding only.

FIGS. 1A, 1B, 1C, and 1D are schematics of tunable hybrid couplers, in accordance with various examples.

FIGS. 2A, 2B, and 2C are graphs illustrating the effects of tuning operations on various properties of a tunable hybrid coupler, in accordance with various examples.

FIGS. 3A, 3B, and 3C are graphs illustrating the effects of tuning operations on various properties of a tunable hybrid coupler, in accordance with various examples.

FIGS. 4 and 5 are schematics of a tuning circuit for tuning capacitors of a tunable hybrid coupler, in accordance with various examples.

FIGS. 6 and 7 are schematics of capacitors of a tunable hybrid coupler, in accordance with various examples.

FIGS. 8A, 8B, and 8C are schematics of tunable hybrid couplers having a tunable phase offset and/or a tunable amplitude offset, in accordance with various examples.

FIG. 9 is a schematic of a circuit component having a tunable characteristic impedance, in accordance with various examples.

FIGS. 10A and 10B illustrate various graphs depicting the effects of tuning operations on various properties of a tunable hybrid coupler in which an amplitude offset is tuned, in accordance with various examples.

FIG. 11 is a schematic of another tunable hybrid coupler having a tunable amplitude offset, in accordance with various example.

FIGS. 12A, 12B, and 12C are schematics of packaging arrangements of a tunable hybrid coupler, in accordance with various examples.

FIG. 13 is a schematic of a system employing one or more tunable hybrid couplers, in accordance with various example.

FIG. 14 is a flowchart of a method of operating a tunable hybrid coupler, in accordance with various example.

### DETAILED DESCRIPTION OF EXAMPLE EMBODIMENTS

As described above, a hybrid coupler splits or combines signals in a balanced and symmetrical manner. Thus, when splitting an input signal into two output signals, the two output signals are at a specific phase offset, such as at 90 degrees or 180 degrees phase offset. Furthermore, output powers of the two output signals are balanced, with substantially no offset therebetween. The hybrid coupler can generate an output signal by combining two input signals having the balanced output powers and having the specific phase offset. Hybrid coupler has ubiquitous applications in radio frequency (RF) world, such as being used as a signal splitter and/or a signal combiner in a Doherty power amplifier, a load modulated power amplifier, etc.

However, due to various reasons, there can be phase and/or amplitude mismatches in the input signals (when used as a signal combiner) or output signals (when used as a signal splitter). For example, due to manufacturing tolerance, there can be mismatches in the lengths and/or characteristic impedances of the input/output signal paths of the hybrid coupler, mismatches in the driver/load impedances, etc., all of which can introduce amplitude mismatches and/or phase mismatches (from the target phase offset) in the input/output signals. Such mismatches can degrade the overall performance of the system that includes the hybrid coupler.

Disclosed herein are techniques and methodology for implementing a tunable hybrid coupler that allows dynamic tuning to reduce or compensate for the phase and amplitude offsets. In a case where the tunable hybrid coupler splits an input signal into two output signals, the tunable hybrid coupler can dynamically tune a phase offset between two output signals to be at the target phase offset (e.g., 90 or 180 degrees, or another configurable angle as desired), and/or dynamically tune an amplitude offset between the two output signals to be at the target amplitude offset (e.g., zero, or another configurable amplitude offset as desired), responsive to a control signal. Also, in a case where the tunable hybrid coupler combines two input signals into an output signal, the tunable hybrid coupler can also be tuned to introduce additional phase offset/amplitude offset to, for example, compensate for the phase offset/amplitude offset between the input signals, or to reduce the phase offset/amplitude offset introduced by the signal paths of the hybrid coupler.

In an example, tuning of the phase offset and tuning of the amplitude offset may be independent from each other. The tunable hybrid coupler may include one or more first tunable components that can provide a tuning range of the phase offset while keeping the amplitude offset constant, or otherwise provide a tuning range of the amplitude offset that is much smaller than the tuning range of the phase offset. Also, the tunable hybrid coupler may include one or more second tunable components that can provide a tuning range of the amplitude offset, while keeping the phase offset constant, or otherwise provide a tuning range of the phase offset that is much smaller than the tuning range of the amplitude offset.

As described above, the tunable hybrid coupler is a four-terminal device, where roles of various terminals are based on whether the tunable hybrid coupler is used as a signal splitter or a signal combiner. For example, when used as a signal splitter, a third terminal receives an input signal, a first terminal and a second terminal provide split output signals, and a fourth terminal acts as an isolation terminal. In such example, the tunable hybrid coupler can dynamically adjust the phase offset/amplitude offset between the second and fourth terminals. The same hybrid coupler may be reconfigured/used as a signal combiner, where the first and second terminals may receive two input signals to be combined, the third terminal may provide the combined signal, and the fourth terminal may act as an isolation terminal.

In an example, the tunable hybrid coupler is a branch line coupler with a first conductor coupled between the first terminal and the second terminal, a second conductor coupled between the first terminal and the third terminal, a third conductor coupled between the second terminal and the fourth terminal, and a fourth conductor coupled between the third terminal and the fourth terminal. Each conductor can be a strip line or an inductor. In an example and for the frequency range of operation of the tunable hybrid coupler, characteristics impedances of the first and third conductors are relatively low, and characteristics impedances of the second and fourth conductors are relatively high. The tunable hybrid coupler also includes a first capacitor is coupled between the first terminal and a ground terminal, a second capacitor is coupled between the second terminal and the ground terminal, a third capacitor is coupled between the third terminal and the ground terminal, and a fourth capacitor is coupled between the fourth terminal and the ground terminal. Each conductor, together with the capacitors on both ends of the conductor, can provide a quarter wavelength transmission line, but the length of each conductor is much shorter than a quarter of the wavelength of the input/output signal due to the presence of the capacitors. Accordingly, the hybrid coupler can become more compact and can be implemented on an integrated circuit die, or as part of package substrate of a packaged integrated circuit.

In an example, the tunable hybrid coupler is a transformer-based coupler and includes a first winding coupled between the first terminal and the third terminal and a second winding between the second terminal and the fourth terminal, with the first and second windings being magnetically coupled or otherwise forming a transformer. In such example, the tunable hybrid coupler includes additional capacitors coupled between the first and second terminals, between the third and fourth terminals, and between the center taps of the first and second windings. The windings can be implemented as part of package substrate of a packaged integrated circuit, or can be external to the packaged IC.

In an example, to support phase offset tuning, one or more of these capacitors are tunable. In an example, the second capacitor and the fourth capacitor may be tuned in a differential manner, to tune the phase offset. In an example, the first capacitor and the second capacitor may be tuned in a similar manner, to tune the phase offset. In an example, the third capacitor may be non-tunable. In an example, a tunable capacitor may be implemented using a varactor and/or a bank of switched capacitors. Also, in an example, to support amplitude offset tuning, the characteristics impedances of the second and fourth conductors are tunable.

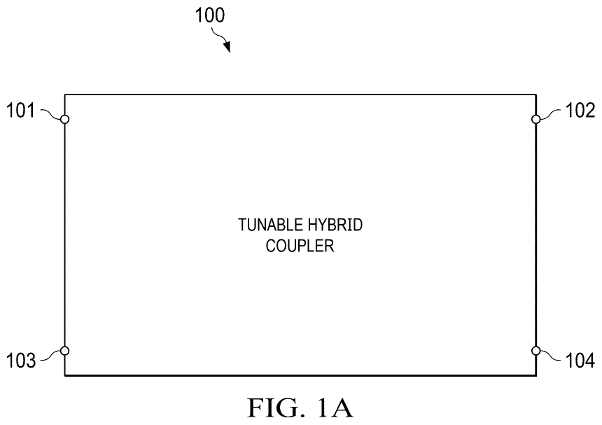

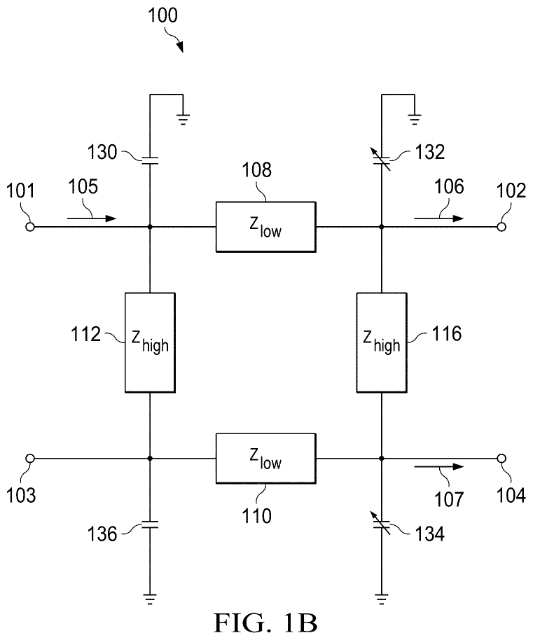

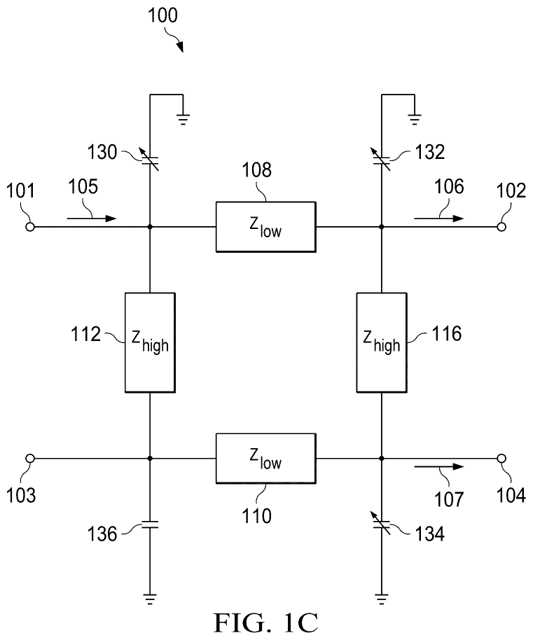

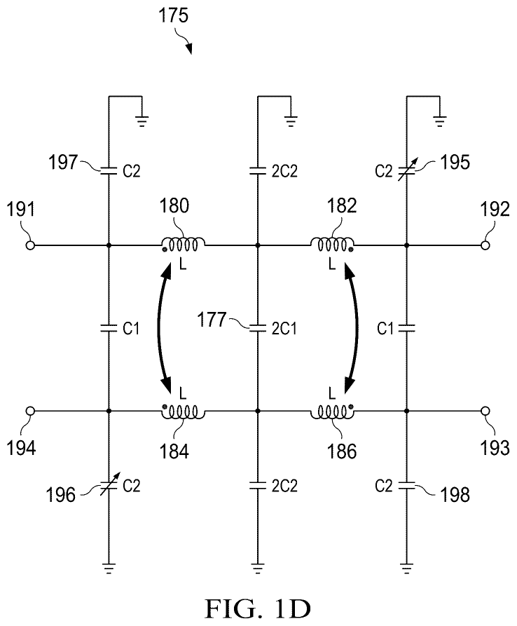

FIG. 1A is a schematic of a tunable hybrid coupler 100, in accordance with at least one example. In an example, tunable hybrid coupler 100 is a 4-port passive circuitry, which may be used in RF (radio frequency) and/or microwave applications. For example, tunable hybrid coupler 100 comprises terminals 101, 102, 103, 104. In one example, terminal 101 may be an input terminal, terminal 103 may be an isolation terminal, and terminals 102, 104 may be two output terminals. However, in another example, terminals 102 and 104 may be two input terminals, terminal 101 may be an output terminal, and terminal 103 may be an isolation terminal. Functionality of terminals 101, . . . , 104 may be based on an application for which tunable hybrid coupler 100 is deployed.

Tunable hybrid coupler 100 is configurable to split or combine signals with tunable phase and amplitude characteristics. In an example, tunable hybrid coupler 100 is operable to split an input signal from an input terminal into two output signals of two output terminals, with a tunable or configurable phase shift between them, as described below in further detail. For example, the phase shift between two output signals can range from (90−a1) degrees to (90+a2) degrees, where a1 and a2 are configurable or tunable parameters. Merely as an example, where a1 and a2 are each equal to 30 degrees, tunable hybrid coupler 100 can achieve a phase shift or phase offset anywhere between 60 degrees and 120 degrees between two output signals. Thus, tunable hybrid coupler 100 can tune phase offset between two output signals.

Additionally (or alternatively), in an example, tunable hybrid coupler 100 can also tune an amplitude offset between two output signals, as described below in further detail. For example, in a non-tunable hybrid coupler, power of the input signal is generally split in about half between two output signals (which are at phase offset with respect to each other). However, tunable hybrid coupler 100 is configurable to tune a power supplied to each of the output signals, which is also referred to herein as amplitude tuning of the output signals.

In an example, tunable hybrid coupler 100 may also operate as a signal combiner, where two input signals in two corresponding input terminals are combined as a single output signal. Tunable hybrid coupler 100 can be tuned to introduce additional phase offset/amplitude offset to, for example, compensate for the phase offset/amplitude offset between the input signals, or to reduce the phase offset/amplitude offset introduced by the signal paths of the hybrid coupler.

FIG. 1B illustrates an example implementation of a tunable hybrid coupler (such as tunable hybrid coupler 100 of FIG. 1A), in accordance with at least one example. For example, tunable hybrid coupler 100 of FIG. 1B comprises terminals 101, 102, 103, and 104. In the example of FIG. 1B, terminal 101 is an input terminal, terminal 103 is an isolation terminal, and terminals 102 and 104 are output terminals. Note that as described above, in another example application of tunable hybrid coupler 100, the role of various terminals may be interchangeable.

In FIG. 1B, input terminal 101 receives an input signal 105, and output terminals 102 and 104 respectively generate output signals 106 and 107. Thus, tunable hybrid coupler 100 splits input signal 105 into output signals 106, 107, and has a configurable and tunable phase offset between output signals 106, 107.

In at least one example, isolation terminal 103 is coupled, through a capacitor 136, either to a ground terminal (e.g., as illustrated in FIG. 1B) or to a power supply rail. In an example, a conductor comprising high impedance signal path Z_{high} 112 is coupled between terminals 101 and 103; a conductor comprising high impedance signal path Z_{high} 116 is coupled between terminals 102 and 104; a conductor comprising low impedance signal path Z_{low} 108 is coupled between terminals 101 and 102; and a conductor comprising low impedance signal path Z_{low} 110 is coupled between terminals 103 and 104. In an example, impedance of each of high impedance signal paths Z_{high} 112, 116 is higher than impedance of each of low impedance signal paths Z_{low} 108, 110, e.g., for a frequency range of operation of tunable hybrid coupler 100. In an example, signals 105, 106, 107 are radio frequency (RF) signals. As illustrated, terminals 101, 102, 103, 104 are DC-shorted (e.g., electrically shorted for DC signals). Accordingly, any DC signal (such as a bias signal or a DC ground voltage signal) in isolation terminal 103 is propagated to DC-shorted terminals 101, 102, and 104. In an example, isolation terminal 103 is coupled to a DC bias or a passive impedance termination, e.g., based on an application of tunable hybrid coupler 100.

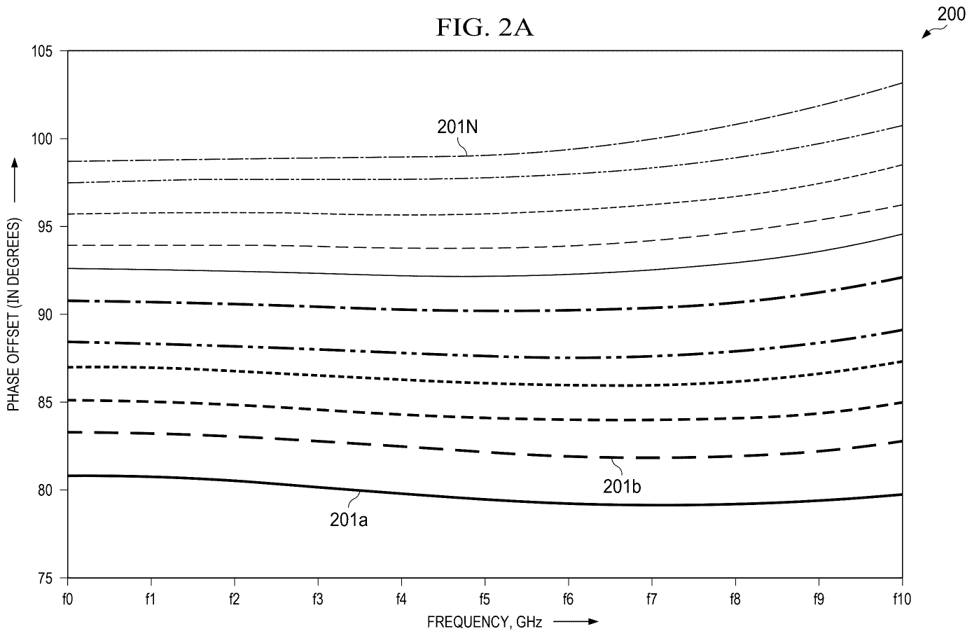

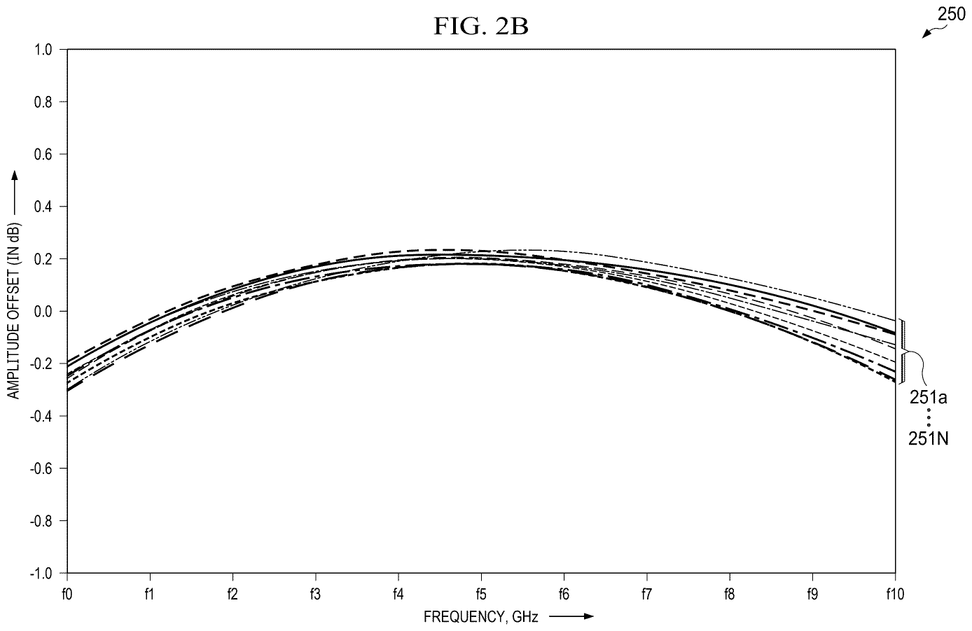

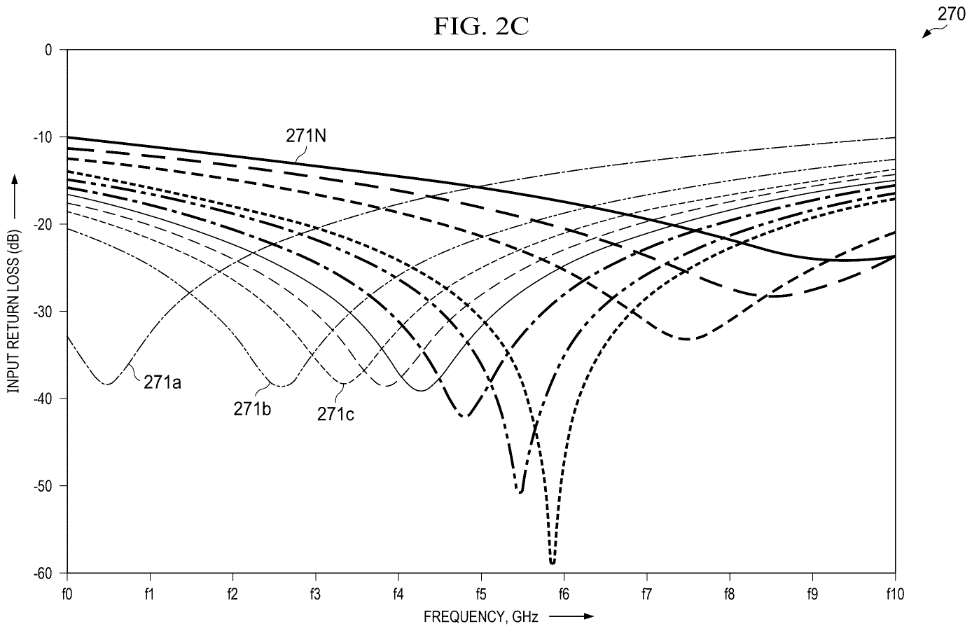

In an example, tunable hybrid coupler 100 further includes a capacitor 130 coupled between terminal 101 and a ground terminal, a capacitor 132 coupled between terminal 102 and another ground terminal, a capacitor 136 coupled between terminal 103 and another ground terminal, and a capacitor 134 coupled between terminal 101 and a ground terminal. Each conductor, together with the capacitors on both ends of the conductor, can provide a quarter wavelength transmission line, but the length of each conductor is much shorter than a quarter of the wavelength of the input/output signal due to the presence of the capacitors. Accordingly, the hybrid coupler can become more compact and can be implemented on an integrated circuit die, or as part of package substrate of a packaged integrated circuit. In an example, one or more of capacitors 130, 132, 134, 136 are tunable. In the example of FIG. 1B, capacitors 132 and 134 are tunable. For example, tuning capacitors 132, 134 facilitate in tuning phase offset between output signals 106, 107. For example, FIGS. 2A, 2B, 2C illustrate various graphs depicting the effect of tuning operations on the properties of tunable hybrid coupler 100 of FIG. 1B, with two tunable capacitors 132, 134 coupled to output terminals 102, 104, respectively. For example, FIG. 2A illustrates a graph 200 depicting a phase offset between output signals 106 and 107 respectively provided at terminals 102, 104, and for various example values of capacitor 132 and capacitor 134. In the example of FIGS. 1B and 2A-2C, capacitor 130 is assumed to have a fixed or non-tunable capacitance.

As illustrated in FIG. 2A, graph 200 includes a plurality of plots 201a, 201b, . . . , 201N in graph 200 are illustrated, where each plot represents the variation of phase offset of tunable hybrid coupler 100 with respect to the frequency of operation for a particular set of capacitance values of capacitors 132 and 134. The X axis of graph 200 represents frequencies f0, f1, . . . , f10 of operation of tunable hybrid coupler 100. The frequencies may be in RF range, such as in Gigahertz (GHz) range, in an example. The Y axis of the graph 200 represents phase offset (in degrees) between output signals 106 and 107 of tunable hybrid coupler 100.

In an example, capacitors 132 and 134 are tuned differentially. For example, an increase in capacitance of capacitor 132 is accompanied by a corresponding decrease in capacitance of capacitor 134; and similarly, an increase in capacitance of capacitor 134 is accompanied by a corresponding decrease in capacitance of capacitor 132. Reasons behind such differential tuning of capacitors 132, 134 have been described below in further detail.

For example, plot 201a corresponds to a relatively lower value of capacitor 134 and a relatively higher value of capacitor 132. In contrast, plot 201N corresponds to a relatively higher value of capacitor 134 and a relatively lower value of capacitor 132. For example, assume that plots 201a, 201b, . . . , 201N correspond to capacitance values C132a, C132b, . . . , C132N of capacitor 132, respectively, and also correspond to capacitance values C134a, C134b, . . . , C134N of capacitor 134, respectively. In such an example, C132a>C132b> . . . >C132N, and C134a<C134b< . . . <C134N. Thus, as capacitance of capacitor 134 increases and as capacitance of capacitor 132 decreases, phase offset increases. For example, phase offset for plot 201a (e.g., with corresponding capacitance values of C132a and C134a for capacitors 132 and 134, respectively, has a phase offset of about 80 degrees for a frequency f5 of operation.

As illustrated in FIG. 2B, graph 250 includes a plurality of plots 251a, 251b, . . . , 251N, where each plot represents the variation of amplitude offset of tunable hybrid coupler 100 with respect to the frequency of operation for a particular set of capacitance values of capacitors 132 and 134. The X axis of graph 200 represents frequencies f0, f1, . . . , f10 of operation of tunable hybrid coupler 100. The Y axis of graph 200 represents amplitude offset (in dB) between output signals 106 and 107 of tunable hybrid coupler 100. The amplitude offset is a difference in supplied power between output signals 106 and 107.

In FIG. 2B, plots 251a, 251b, . . . , 251N corresponds to capacitance values C132a, C132b, . . . , C132N of capacitor 132, respectively, and also corresponds to capacitance values C134a, C134b, . . . , C134N of capacitor 134, respectively. Comparing FIGS. 2A and 2B, variation and tuning of capacitors 132, 134 do not significantly impact the amplitude offset (e.g., compared to an impact on the phase offset).

Thus, as illustrated in FIGS. 2A-2B, differential variation in capacitance values of capacitors 132, 134 can be used to tune phase offset between output signals 106, 107, without significantly affecting amplitude offset between output signals 106, 107. Thus, differential variation in capacitance values of capacitors 132, 134 can be used to tune phase offset, independent of amplitude offset between output signals 106, 107 of tunable hybrid coupler 100.

As illustrated in FIG. 2C, graph 270 includes a plurality of plots 271a, 271b, . . . , 271N in a graph 270, where each plot represents the variation of input return loss of tunable hybrid coupler 100 with respect to the frequency of operation for a particular set of capacitance values of capacitors 132 and 134. The X axis of graph 200 represents frequencies f0, f1, . . . , f10 of operation of tunable hybrid coupler 100. The Y axis of graph 200 represents input return loss (in dB). A target return loss (e.g., −10 dB or less) may impose a limit on the phase tuning range.

FIG. 1C illustrates another example implementation of a tunable hybrid coupler 100, in accordance with at least one example. For example, in FIG. 1B, each of capacitors 132, 134 are tunable. In FIG. 1C, each of capacitors 130, 132, 134 are tunable. Tuning capacitor 130, in addition to capacitors 132, 134, results in an addition degree of freedom in tuning phase offset between output signals 106, 107.

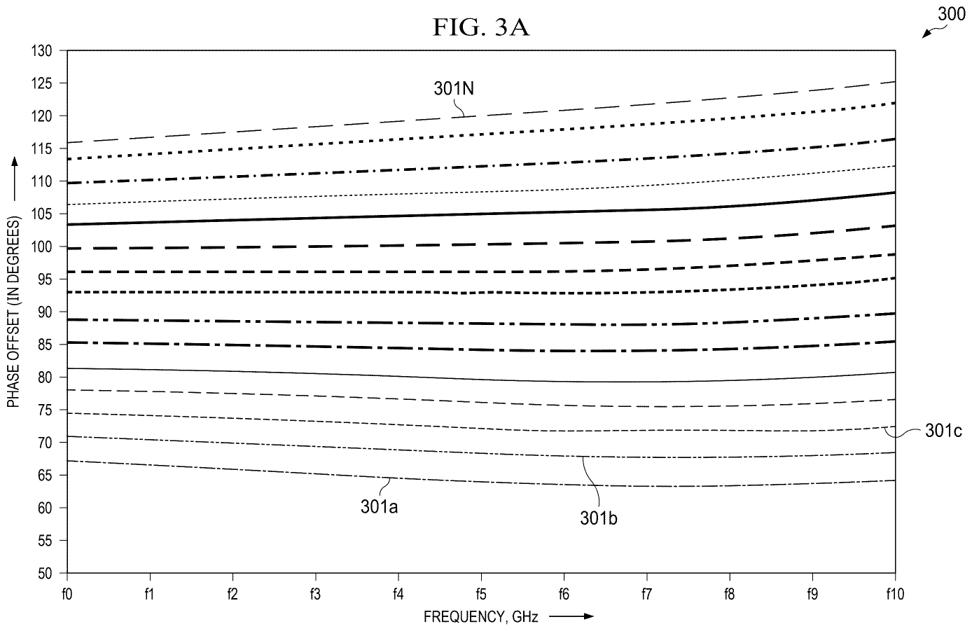

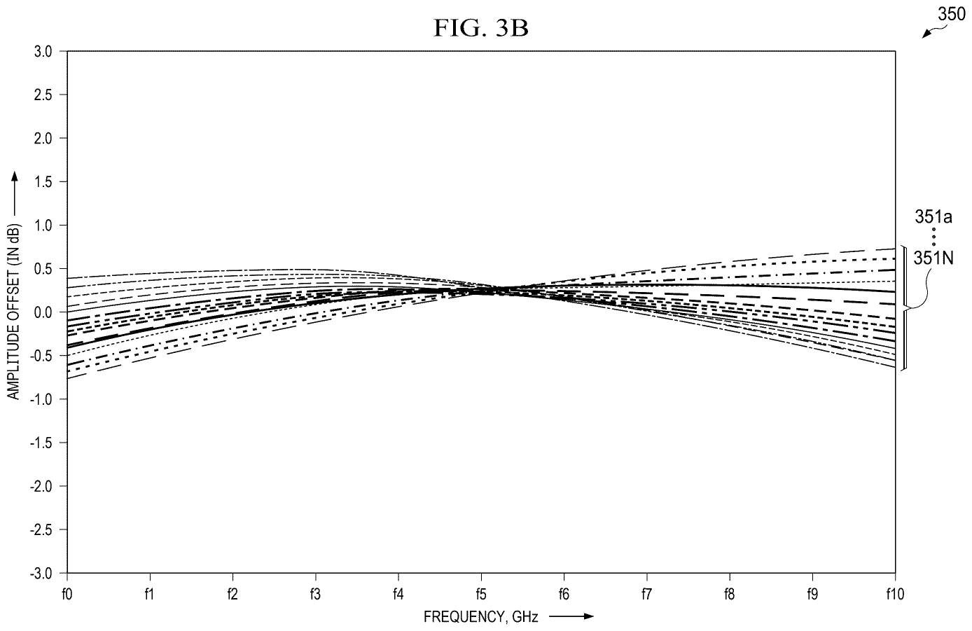

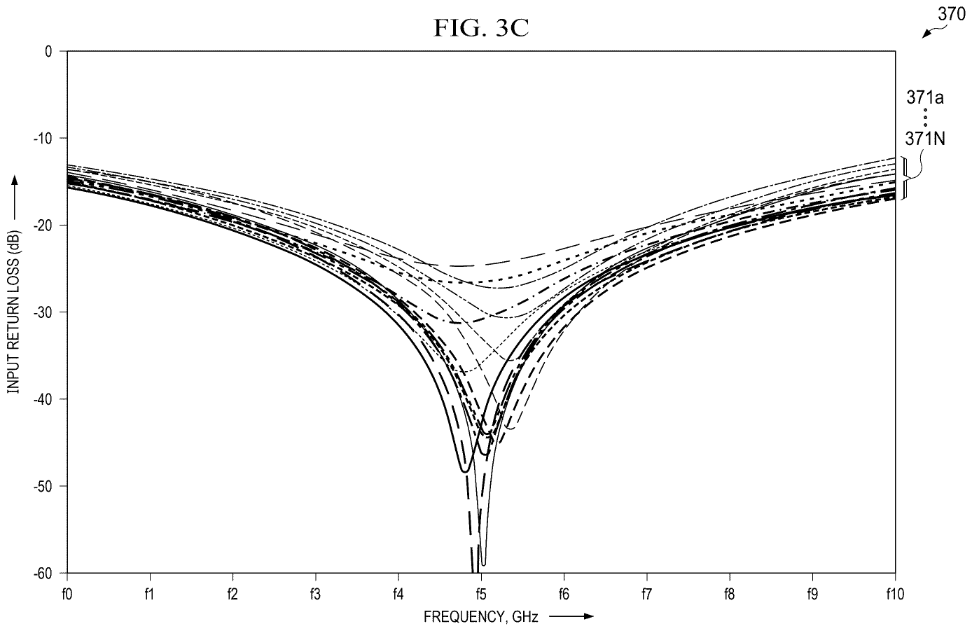

For example, FIGS. 3A, 3B, 3C illustrate various graphs depicting operation of tunable hybrid coupler 100 of FIG. 1C, with three tunable capacitors 130, 132, 134 coupled to three corresponding terminals 101, 102, 104, respectively. For example, FIG. 3A illustrates a graph 300 depicting a phase offset between output signals 106 and 107 respectively provided at terminals 102, 104 of FIG. 1C, and for various example values of capacitors 132, 134, and 130. In the example of FIGS. 1C and 3A-3C, all three capacitors 130, 132, 134 are tunable.

As illustrated in FIG. 3A, graph 300 includes a plurality of plots 301a, 301b, . . . , 301N where each plot represents the variation of phase offset of tunable hybrid coupler 100 with respect to the frequency of operation for a particular set of capacitance values of capacitors, 130, 132 and 134. The X axis of graph 300 represents frequencies f0, f1, . . . , f10 of operation of tunable hybrid coupler 100. The Y axis of graph 300 represents phase offset (in degrees) between output signals 106 and 107 of tunable hybrid coupler 100.

In an example, capacitors 132 and 134 are tuned differentially (e.g., as also described above with respect to FIGS. 1B and 2A-2C). For example, an increase in capacitance of capacitor 132 is accompanied by a corresponding decrease in capacitance of capacitor 134; and similarly, an increase in a capacitance of capacitor 134 is accompanied by a corresponding decrease in capacitance of capacitor 132. In FIG. 3A, as capacitance of capacitor 134 increases and as capacitance of capacitor 132 decreases, phase offset corresponding increases. Furthermore, as capacitance of capacitor 130 increases, phase offset corresponding decreases.

Comparing FIGS. 2A and 3A, in FIG. 2A, a tunable range of phase offset was between about 80 degrees to about 103 degrees for frequency range f0 to f10. In contrast, in FIG. 3A, a tunable range of phase offset is between about 65 degrees to about 125 degrees for frequency range f0 to f10. Thus, by tuning capacitor 130, in addition to tuning capacitors 132 and 134, can facilitate in increasing a range of phase offset that can be achieved through capacitor tuning.

Referring now to FIG. 3B, graph 350 includes a plurality of plots 351a, 351b, . . . , 351N, where each plot represents the variation of amplitude offset of tunable hybrid coupler 100 with respect to the frequency of operation for a particular set of capacitance values of capacitors 130, 132 and 134. The X axis of graph 300 represents frequencies f0, f1, . . . , f10 of operation of tunable hybrid coupler 100 of FIG. 1C. The Y axis of graph 300 represents amplitude offset (in dB) between output signals 106 and 107 of tunable hybrid coupler 100 of FIG. 1C. The amplitude offset is a difference in power between output signals 106 and 107.

In FIG. 3B, plots 351a, 351b, . . . , 351N corresponds to various values of capacitors 130, 132, 134. As illustrated, variation and tuning of capacitors 130, 132, 134 do not significantly impact amplitude offset (e.g., compared to an impact on phase offset).

Thus, as illustrated in FIGS. 3A-3B, differential tuning of capacitors 132, 134 and tuning of capacitor 130 can be used to tune phase offset between output signals 106, 107, without significantly affecting amplitude offset between output signals 106, 107.

As illustrated in FIG. 3C, graph 370 includes a plurality of plots 371a, 371b, . . . , 371N, where each plot represents the variation of input return loss of tunable hybrid coupler 100 with respect to the frequency of operation for a particular set of capacitance values of capacitors 130, 132, and 134. The X axis of graph 200 represents frequencies f0, f1, . . . , f10 of operation of tunable hybrid coupler 100. The Y axis of graph 200 represents input return loss (in dB). Comparing FIGS. 2C and 3C, input loss parameters in FIG. 3C are relatively better than input loss parameters in FIG. 2C, in that the return losses are more uniform across the different capacitance values and center at a particular frequency.

The following provides an explanation of the theory behind the improvement of the phase offset of a hybrid coupler based on tuning of capacitors 130,132, 134, assume that an impedance of each of conductors 112 and 116 is Z2, and an impedance of each of conductors 108 and 110 is Z1. Also assume that an electrical length of each of conductors 112 and 116 is E2, and an electrical length of each of conductors 108 and 110 is E1.

Assume the following input parameters: (i) target phase imbalance Φ, (ii) target electrical lengths E1 and E2, and (iii) center operating frequency ω and Zo. For various the components value that achieve amplitude independent phase tuning using port decomposition method, the following can be derived:

$$Z 1 = \frac{Z 0 \times sin ( ∅ )}{\sqrt{2} \times sin ( E 1 )} , \qquad Equation 1$$

$$Z 2 = \frac{Z 0 \times sin ( ∅ )}{sin ( E 2 )} , \qquad Equation 2$$

$$Ctune 1 = \frac{\sqrt{2} + 1 - \sqrt{2} sin ( E 1 ) tan ( \frac{E 1}{2} ) - sin ( E 2 ) tan ( \frac{E 2}{2} )}{Z 0 \times sin ( ∅ ) \times ω o} - \frac{cos ( ∅ )}{Z 0 \times sin ( ∅ ) \times ω o} , \qquad Equation 3$$

$$Ctune 2 = \frac{\sqrt{2} + 1 - \sqrt{2} sin ( E 1 ) tan ( \frac{E 1}{2} ) - sin ( E 2 ) tan ( \frac{E 2}{2} )}{Z 0 \times sin ( ∅ ) \times ω o} + \frac{cos ( ∅ )}{Z 0 \times sin ( ∅ ) \times ω o} . \qquad Equation 4$$

In equations 3 and 4, Ctune1 is representative of capacitors 130, 132, and Ctune2 is representative of capacitors 136, 134. In each of equations 3 and 4, there are two components: a first component is a common component, and a second term is a differential component.

In an example, although Ctune2 is representative of capacitors 134 and 136, not tuning capacitor 136 may not affect the phase offset significantly. For example, tuning or not tuning capacitor 136 may provide substantially similar results (or at least satisfactory results). As isolation terminal 103 is isolated to an extent from other terminals 101, 102, 104, there may not be significant value of signal delivered into isolation terminal 103. Accordingly, in accordance with equations 1-4, phase offset @ can be tuned by tuning capacitors 130, 132, 134. Furthermore, due to the presence of the differential components in equations 3 and 4, in an example, capacitors 132, 134 may be tuned differentially. Furthermore, in an example, capacitors 130, 132 may be tuned in a similar manner (e.g., see FIG. 1C). For example, an increase in capacitor 132 may be accompanied by a corresponding increase in capacitor 130, and vice versa.

FIG. 1D illustrates another example implementation of a tunable hybrid coupler 175, in accordance with at least one example. For example, tunable hybrid coupler 175 comprises terminals 191, 192, 193, and 194. In an example, terminal 191 is an input terminal, terminal 193 is an isolation terminal, and terminals 192 and 194 are output terminals. Note that as described above, in another example application of tunable hybrid coupler 175, role of various terminals may be interchangeable. Tunable hybrid coupler 175 comprises a transformer coupler with center taps and coupling capacitors at the terminals and the center taps. For example, a first winding comprising inductors/coils 180 and 182 is coupled between terminals 191 and 192, and a second winding comprising inductors/coils 184 and 186 is coupled between terminals 194 and 193. The first winding comprising inductors/coils 180 and 182 is magnetically coupled to the second winding comprising inductors/coils 184 and 186. A center tap of the first winding is coupled to a center tap of the second winding through a capacitor 177. In an example, tunable hybrid coupler 175 comprises a plurality of capacitors, one or more of which are tunable. The structure of tunable hybrid coupler 175, without any tuning capability of the capacitors, are described in co-pending patent U.S. patent application Ser. No. 18/651,514, filed Apr. 30, 2024, and entitled Power Amplifier Combiner, entirety of which is incorporated by reference herein. In an example, capacitors 195 and 196 may be tuned, e.g., to corresponding tune a phase offset of output signals of tunable hybrid coupler 175. In an example, capacitors 195 and 196 may be tuned differentially, as also described above. In an example, in addition to (or instead of) capacitors 195, 196, capacitors 197, 198 may also be tuned, e.g., to tune achieve a desired phase offset between two output signals.

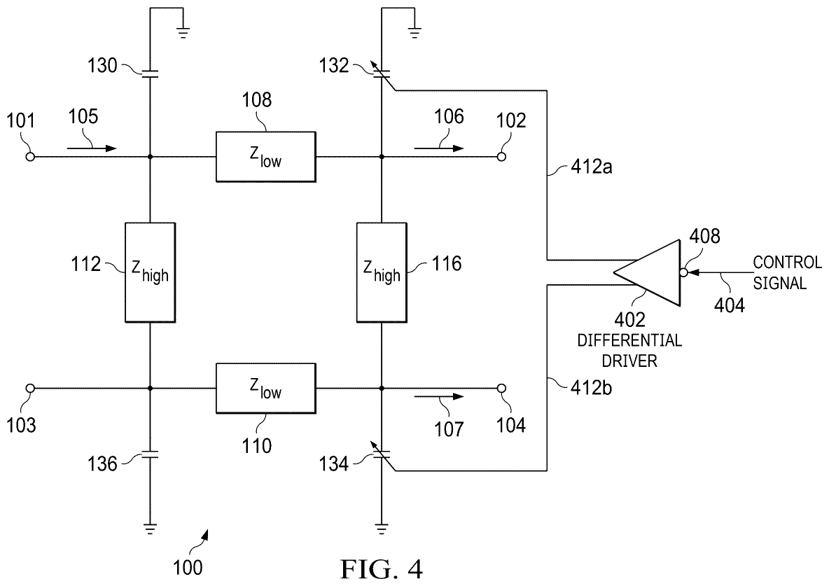

FIG. 4 is a schematic of a tuning circuit for tuning capacitors 132, 134 of a tunable hybrid coupler (e.g., tunable hybrid coupler 100 of FIGS. 1B and 1C), in accordance with at least one example. As described above with respect to FIGS. 1B and 1C, capacitors 132, 134 are tuned in a differential manner. For example, an increase in capacitance of capacitor 132 may be accompanied by a corresponding decrease in capacitance of capacitor 134, and/or a decrease in capacitance of capacitor 132 may be accompanied by a corresponding increase in capacitance of capacitor 134. For example, an amount or percentage of increase in one capacitance is accompanied by a substantially same (e.g., within 10% or within 5%) decrease in the other capacitance. In an example, tunable hybrid coupler 100 of FIG. 4 comprises a differential driver circuit 402 that receives a control signal 404 at a control terminal of differential driver circuit 402. Based on control signal 404, differential driver circuit 402 outputs control signals 412a and 412b.

In an example, control signals 412a and 412b are respectively used to tune capacitors 132, 134. For example, a change in control signal 412a may result in a corresponding change in capacitance of capacitor 132, and a change in control signal 412b may result in a corresponding change in capacitance of capacitor 134. Capacitors 132, 134 are varactors, for example.

In an example, control signals 412a and 412b are differential signals, such that an increase in control signal 412a results in corresponding decrease in control signal 412b, and a decrease in control signal 412a results in corresponding increase in control signal 412b. In an example, control signal 404 dictates which of control signals 412a, 412b will increase and by what amount (or will remain stable), thereby also controlling capacitances of capacitors 132, 134. In an example, differential driver circuit 402 may be an appropriate differential driver circuit generating differential output signals, based on an input signal.

Although FIG. 4 does not illustrate tuning of capacitor 130, in an example, capacitor 130 may also be tuned by any of control signals 412a, 412b, or another control signal. In an example, where capacitor 130 may be tuned similar to one of capacitors 132 or 134, corresponding control signal 412a or 412b may also be provided to capacitor 130.

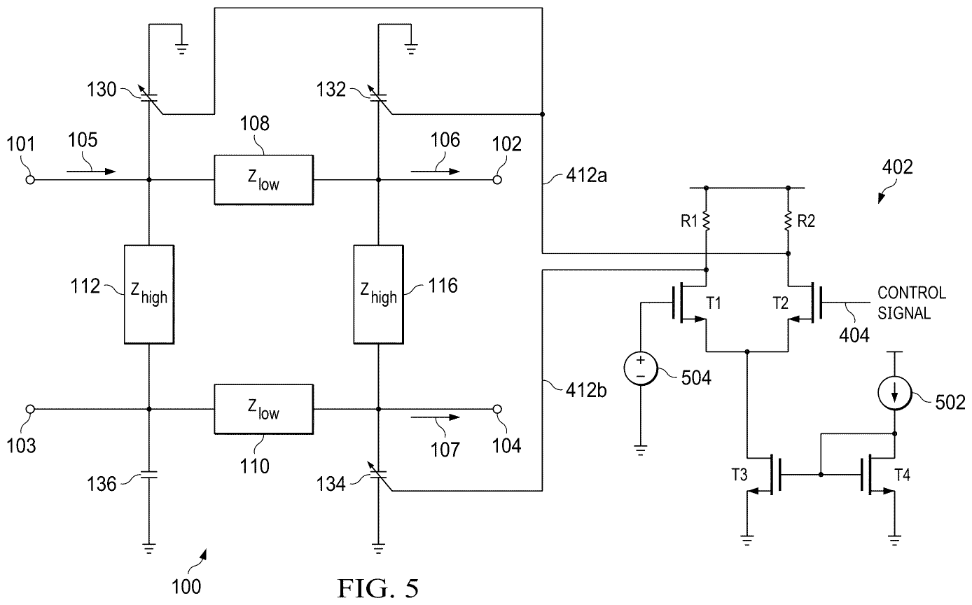

FIG. 5 is a schematic of a differential driver circuit 402 configurable to tune capacitors 132, 134 of a tunable hybrid coupler (e.g., tunable hybrid coupler 100 of FIGS. 1B and 1C), in accordance with at least one example. Thus, FIG. 5 illustrates an example implementation of differential driver circuit 402 of FIG. 4. Differential driver circuit 402 comprises transistors T1, T2, T3, T4, a current source 502, a voltage source 504, and resistors R1 and R2 coupled in the manner illustrated in FIG. 5.

Transistors T1 and T2 (such as NMOS transistors) form a differential pair of transistors. Transistors T3 and T4 form a current mirror. Current source 502 provides current for differential pairs of transistors T1 and T2, through the current mirror. Control signal 404 applied to a gate terminal of transistor T2 acts as a reference voltage for comparison in the differential pair of transistors T1 and T2, and controls the output of differential driver circuit 402, which are control signals 412a, 412b. Although an example architecture of differential driver circuit 402 is illustrated in FIG. 5, another appropriate differential driver circuit may also be used instead.

In an example, capacitor 130 may also be tuned by any of control signals 412a, 412b, or another control signal. For example, capacitor 130 may be tuned similar to capacitor 132, and corresponding control signal 412a may also be provided to tune capacitor 130, as illustrated in FIG. 5.

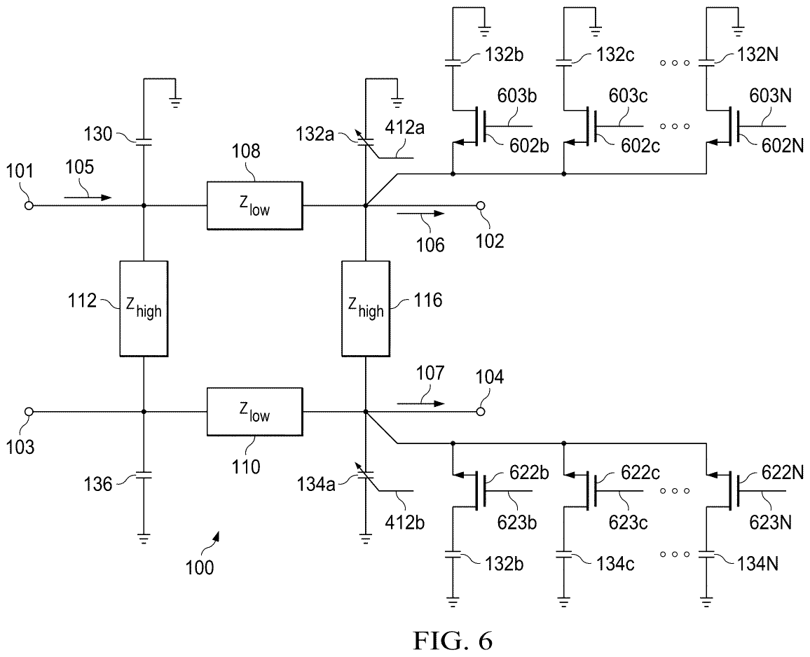

FIG. 6 is a schematic of tunable capacitors of a tunable hybrid coupler (e.g., tunable hybrid coupler 100 of FIGS. 1B and 1C), in accordance with at least one example. For example, capacitor 132 is divided into a plurality of capacitors 132a, 132b, . . . , 132N, and capacitor 134 is divided into a plurality of capacitors 134a, 134b, . . . , 134N. In an example, the capacitors 132a and 134a are varactors, and are tunable using corresponding analog control signals (such as control signals 412a, 412b described above with respect to FIG. 4).

Also, each of capacitors 132b, . . . , 132N is either selectively coupled or decoupled from corresponding terminal 102 via corresponding switching arrangement (e.g., comprising a corresponding transistor). For example, capacitor 132b is coupled to terminal 102 through a transistor 602b, and is also coupled to ground terminal, where control signal 603b controls switching on and off of transistor 602b. Similarly, capacitor 132N is coupled to terminal 102 through a transistor 602N, and is also coupled to ground terminal, where control signal 603N controls switching on and off of transistor 602N. Other capacitors of capacitor bank 132c, . . . , 132(N−1) have similar connections. For example, control signal 603b controls as to whether corresponding capacitor 132b is coupled to (or decoupled from) terminal 102, e.g., by controlling on or off state of corresponding transistor 602b.

Thus, digital control signals 603b, . . . , 603N, along with analog signal 412a, controls effective capacitance coupled to terminal 102. In an example, capacitor 132a (such as a varactor) may be used for coarse control of capacitance coupled to terminal 102, while individual ones of bank of capacitors 132b, . . . , 132N may be switched on or off and used for fine control of capacitance coupled to terminal 102.

Similarly, capacitors 134b, . . . , 134N are controllable using corresponding digital control signals 623b, . . . , 623N, respectively. For example, capacitor 134b is coupled to terminal 104 through a transistor 622b, and is also coupled to ground terminal, where control signal 623b controls switching on and off of transistor 622b. Similarly, capacitor 134N is coupled to terminal 104 through a transistor 622N, and is also coupled to ground terminal, where control signal 623N controls switching on and off of transistor 622N. Other capacitors of capacitor bank 134c, . . . , 134(N−1) have similar connections. Operation of capacitors 134a, 134b, . . . , 134N will be self-evident, based on the above discussion with respect to capacitors 132a, 132b, . . . , 132N.

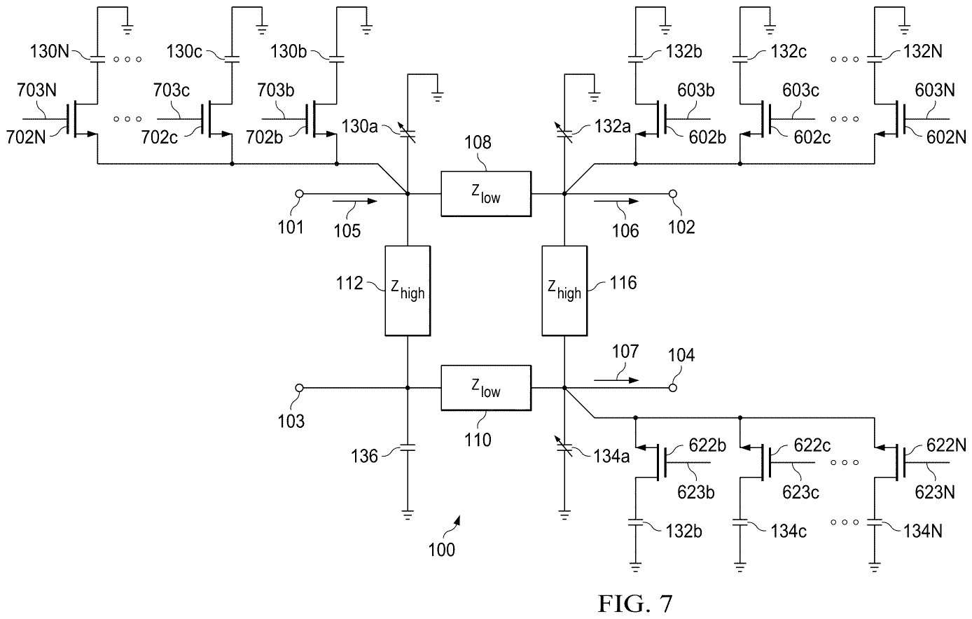

FIG. 7 is a schematic of tunable capacitors of a tunable hybrid coupler (e.g., tunable hybrid coupler 100 of FIGS. 1B and 1C), in accordance with at least one example. For example, in FIG. 6, each of capacitors 132 and 134 were divided into multiple capacitors. In contrast, in FIG. 7, each of capacitors 132 and 134, as well as capacitor 130, is divided into multiple capacitors. For example, capacitor 130 is divided into a plurality of capacitors 130a, 130b, . . . , 130N. Capacitor 130a may be a varactor tunable using an analog control signal. Also, capacitors 130b, . . . , 130N are controllable using corresponding digital control signals 703b, . . . , 703N, respectively, e.g., using a corresponding plurality of transistors 702a, . . . , 702N. For example, capacitor 130b is coupled to terminal 101 through a transistor 702b, and is also coupled to ground terminal, where control signal 703b controls switching on and off of transistor 702b. Other capacitors of capacitor bank 130b, . . . , 130(N−1) have similar connections. Operation of capacitors 130a, 130b, . . . , 130N will be self-evident, based on the above discussion with respect to capacitors 132a, 132b, . . . , 132N.

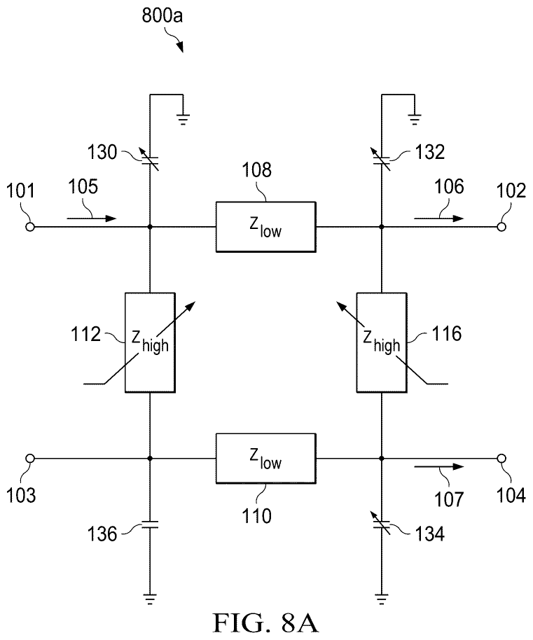

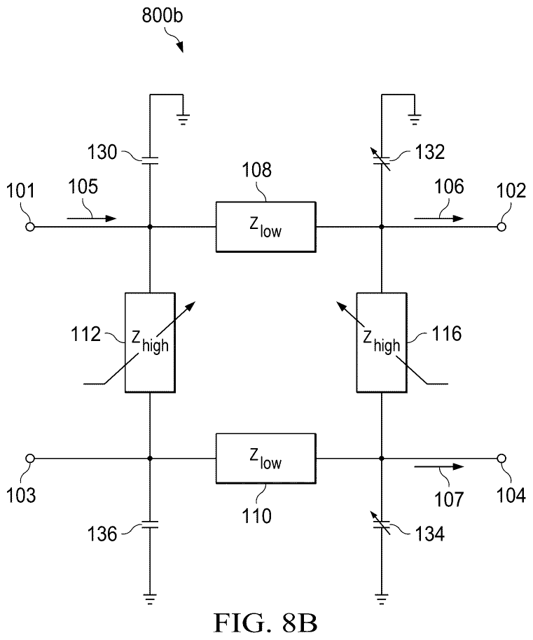

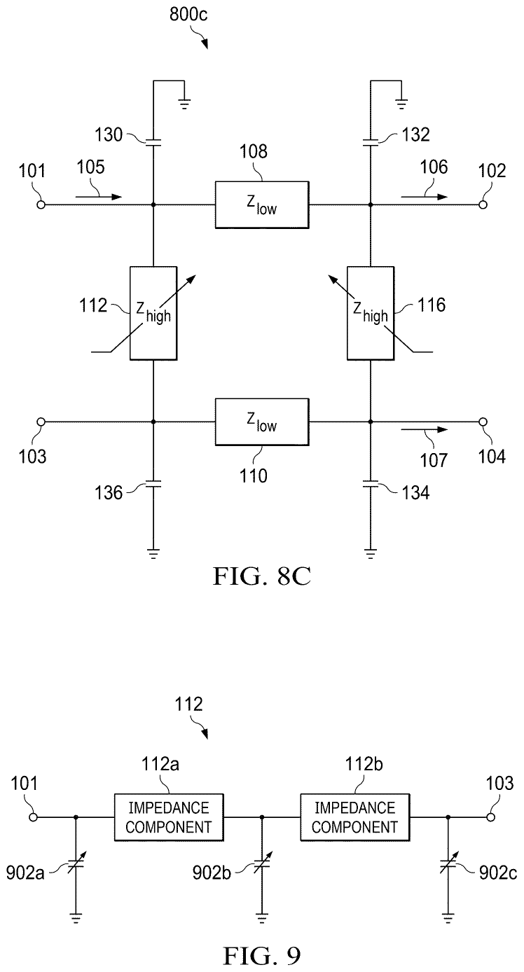

FIG. 8A is a schematic of a tunable hybrid coupler 800a in which a phase offset and/or an amplitude offset of the tunable hybrid coupler are tunable, in accordance with at least one example. For example, tunable hybrid coupler 800a of FIG. 8A is at least in part similar to tunable hybrid coupler 100 of FIG. 1B, and like components in tunable hybrid couplers 100 and 800a are labelled using the same labels.

Similar to tunable hybrid coupler 100, tunable hybrid coupler 800a comprises terminals 101, 102, 103, 104, with relatively low impedance conductors Z_{low} 108 and Z_{low} 110, and relatively high impedance conductors Z_{high} 112 and 116 between various terminals, as illustrated. Furthermore, capacitors 130, 132, 134, 136 are coupled to terminals 101, 102, 104, and 103, respectively. In the example of FIG. 8A (and similar to FIG. 1B), capacitors 130, 132, 134 are tunable, which may be used to tune phase offset between output signals 106, 107, as described above.

Additionally, in tunable hybrid coupler 800a, high impedance conductors Z_{high} 112 and 116 are also tunable. In an example, tuning high impedance conductors Z_{high} 112 and 116 results in tuning of amplitude offset between output signals 106, 107. In an example (e.g., for specific values of high impedance conductors Z_{high} 112 and 116), input power in input signal 105 may be divided equally to output signals 106, 107. However, tuning high impedance conductors Z_{high} 112 and 116 results in asymmetrical power distribution among output signals 106, 107, referred to as amplitude imbalance and expressed in, for example, dB. In an example, both high impedance conductors Z_{high} 112 and 116 are tuned in a similar manner (e.g., an increase in Z_{high} 112 is accompanied by a corresponding increase in Z_{high} 112, and a decrease in Z_{high} 112 is accompanied by a corresponding decrease in Z_{high} 112).

FIG. 8B is another schematic of a tunable hybrid coupler 800b in which a phase offset and/or an amplitude offset of the tunable hybrid coupler are tunable, in accordance with at least one example. For example, tunable hybrid coupler 800b of FIG. 8B is at least in part similar to tunable hybrid coupler 800a of FIG. 8A, and like components in tunable hybrid couplers 800a and 800b are labelled using the same labels. However, in tunable hybrid coupler 800a, capacitors 130, 132, 134 are tunable. In contrast, in tunable hybrid coupler 800b, capacitors 132, 134 are tunable, while capacitor 130 is not tunable. Note that as described above, phase offset in a tunable hybrid coupler may be performed by tuning capacitors 132, 134, or by tuning capacitors 130, 132, 134. As described below in further details, amplitude tuning by adjusting high impedance conductors Z_{high} 112 and 116 may be independent of tuning of capacitors 130, 132, and/or 134.

FIG. 8C is another schematic of a tunable hybrid coupler 800c in which an amplitude offset of a tunable hybrid coupler is tunable, in accordance with at least one example. For example, tunable hybrid coupler 800c of FIG. 8C is at least in part similar to tunable hybrid coupler 800a of FIG. 8A, and like components in tunable hybrid couplers 800a and 800c are labelled using the same labels. However, in tunable hybrid coupler 800a, capacitors 130, 132, 134 are tunable. In contrast, in tunable hybrid coupler 800c, capacitors 130, 132, 134 are not tunable. Thus, tunable amplitude offset is achievable in tunable hybrid coupler 800c.

FIG. 9 is a schematic of conductor Z_{high} 112 having a tunable characteristic impedance, in accordance with at least one example. Tunable high impedance conductor Z_{high} 116 may have similar structure.

Between input terminal 101 and isolation terminal 103 are a plurality of impedance components 112a, 112b, which are not tunable. The impedance components 112a, 112b may comprise resistors and/or inductors. A first tunable capacitor 902a is coupled between terminal 101 and ground terminal. A second tunable capacitor 902b is coupled between impedance components 112a, 112b and ground terminal. A third tunable capacitor 902c is coupled between terminal 103 and ground terminal. Capacitors 902a, 902b, and/or 903c are tuned, e.g., to tune an overall impedance of the tunable high impedance conductor Z_{high} 112. In an example, a control signal may be used to tune capacitors 902a, 902b, and/or 903c.

Note that while FIG. 9 illustrates one example manner of tuning high impedance conductor Z_{high} 112, any other appropriate manner to tune high impedance conductor Z_{high} 112 may also be possible. Also, a number of impedance components 112a, 112b and/or a number of tunable capacitors 902a, 902b, 902c illustrated in FIG. 9 may be implementation specific, and may vary from one example to the next.

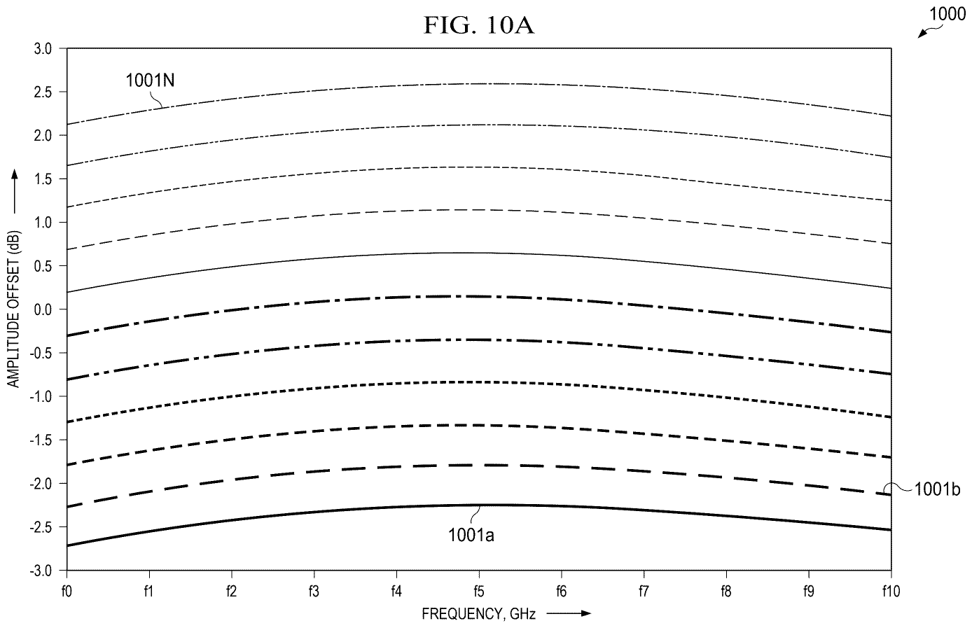

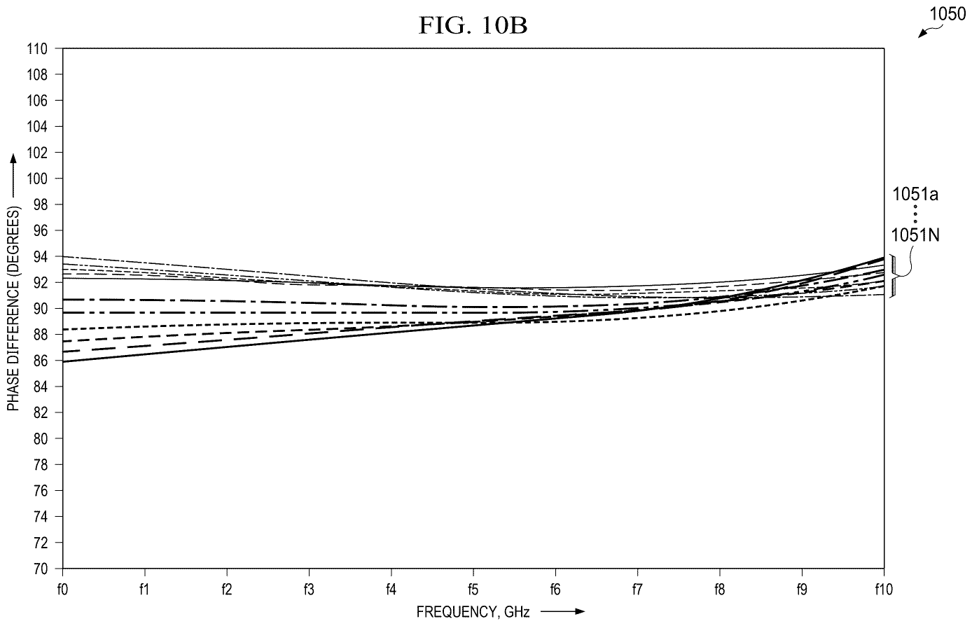

FIGS. 10A and 10B illustrate various graphs depicting the effect of amplitude offset tuning operations on various characteristics of a tunable hybrid coupler (such as any of the tunable hybrid couplers of FIGS. 8A-8C), in accordance with at least one example. For example, FIG. 10A illustrates a graph 1000 depicting an amplitude offset between signals 106 and 107, respectively provided at terminals 102, 104, and for various example values of high impedance conductors Z_{high} 112 and 116. For various plots illustrated in FIGS. 10A and 10B, capacitors 130, 132, 134 are assumed to be fixed or non-tunable.

In FIG. 10A, graph 1000 includes a plurality of plots or plots 1001a, 1001b, . . . , 1001N, where each plot represents the variation of amplitude offset with respect to frequency of operation for a specific set of characteristic impedance values of tunable high impedance conductors Z_{high} 112, 116. The X axis of graph 1000 represents frequencies f0, f1, . . . , f10 of operation of tunable hybrid coupler 100. Frequencies f0, . . . , f10 may be in RF range, such as in Gigahertz (GHz) range, in an example. The Y axis of the graph 1000 represents amplitude offset (in dB) between output signals 106 and 107.

In an example, tunable high impedance conductors Z_{high} 112, 116 are tuned similarly (such that their values are within 5% or 10% of each other). For example, an increase in characteristic impedance of tunable high impedance conductor Z_{high} 112 is accompanied by a correspond increase in characteristic impedance of tunable high impedance conductor Z_{high} 116, and vice versa.

For example, plot 1001a corresponds to relatively lower values of impedances of high impedance conductors Z_{high} 112, 116. In contrast, plot 1001N corresponds to relatively higher values of impedances of high impedance conductors Z_{high} 112, 116.

In FIG. 10B, graph 1050 includes a plurality of plots 1051a, 1051b, . . . , 1051N, where each plot represents the variation of phase offset with respect to frequency of operation for a specific set of characteristic impedance values of high impedance conductors Z_{high} 112, 116. The X axis of graph 1050 represents frequencies f0, f1, . . . , f10 of operation of the tunable hybrid coupler. The Y axis of graph 1050 represents phase offset (in dB) between output signals 106 and 107. The phase offset in FIG. 10B is relatively small or negligible compared to the amplitude offset in FIG. 10A. Thus, the amplitude offset of the tunable hybrid couplers described herein can be tuned independent of the phase offset.

The following provides an explanation of the theory behind the improvement of the amplitude offset based on tuning of high impedance conductors Z_{high} 112, 116. Assume the following parameters: (i) target amplitude imbalance n (n=2 implies−3 dB imbalance, n=0.5 implies+3 dB imbalance, and so on), (ii) target electrical length E1 of low impedance conductors Z_{low} 108, 110, (iii) target electrical length E2 of high impedance conductors Z_{high} 112, 116, (iv) characteristic impedance of low impedance conductors Z_{low} 108, 110 is Z1, and (v) characteristic impedance of high impedance conductors Z_{high} 112, 116 is Z2. Also assume that capacitor 132 and/or capacitor 134 have a capacitance of Ctune. It can be shown using port decomposition method the following:

$$Z 1 = \frac{Z 0}{\sqrt{n + 1} \times sin ( E 1 )} . \qquad Equation 5$$

$$Z 2 = \frac{Z 0}{\sqrt{n + 1} \times sin ( E 2 )} . \qquad Equation 6$$

$$Ctune = \frac{\begin{matrix}\sqrt{n + 1} ( 1 - sin ( E 1 ) tan ( \frac{E 1}{2} ) ) + \\ \sqrt{n} ( 1 - sin ( E 2 ) tan ( \frac{E 2}{2} ) )\end{matrix}}{Z 0 \times sin ( ∅ ) \times ω o} . \qquad Equation 7$$

Thus, a target imbalance n can be achieved by tuning impedance Z2 of high impedance conductors Z_{high} 112, 116. In an example, a tuning range of Z1 is smaller than a tuning range of Z2. Accordingly, impedance Z2 (e.g., high impedance conductors Z_{high} 112, 116) are tuned to control amplitude offset n, in accordance with equations 5, 6, and 7. For example, impedance of low impedance conductors Z_{low} 108, 110 may be fixed, and high impedance conductors Z_{high} 112, 116 are tuned.

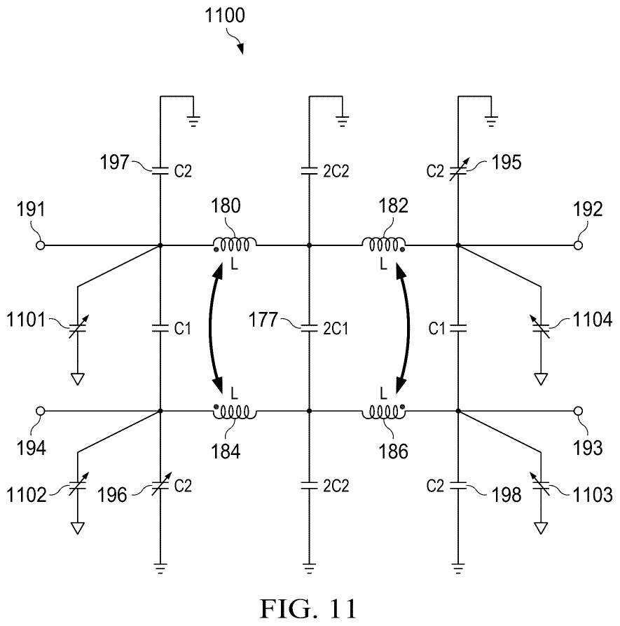

FIG. 11 is a schematic of a tunable hybrid coupler 1100 in which an amplitude offset is tunable, in accordance with at least one example. For example, tunable hybrid coupler 1100 is at least in part similar to tunable hybrid coupler 175 of FIG. 1D. Tunable hybrid coupler 1100 of FIG. 11 comprises tunable amplitude offset characteristics. For example, impedance of one or more conductors of tunable hybrid coupler 1100 are tuned using tunable capacitors 1101, 1102, 1103, and/or 1104, which results in tuning of amplitude offset in output signals at output terminals of tunable hybrid coupler 1100.

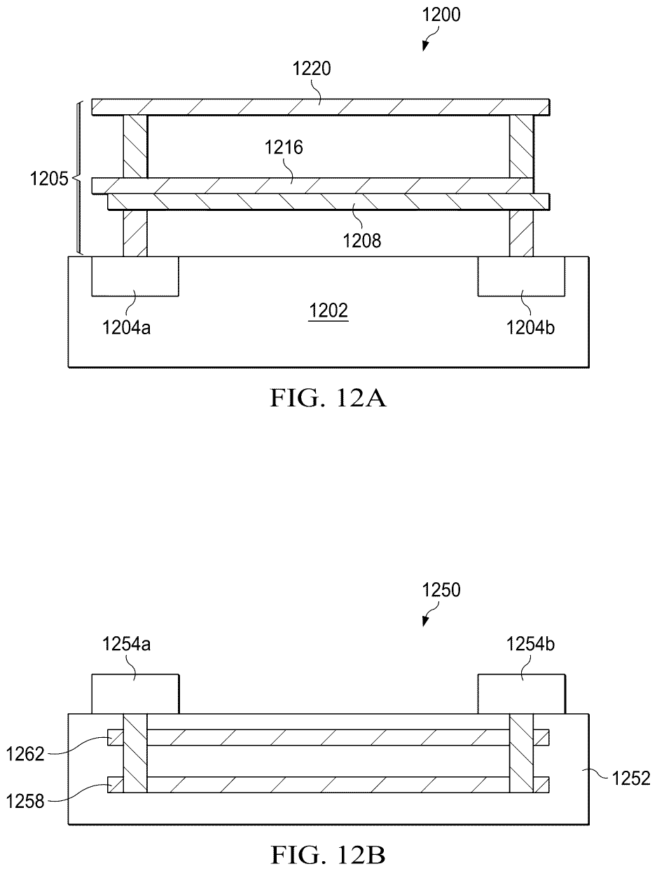

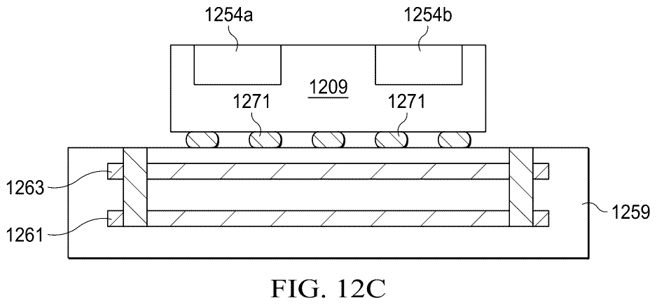

FIG. 12A is a schematic of a packaged integrated circuit 1200 comprising a tunable hybrid coupler, in accordance with at least one example. The integrated circuit 1200 comprises a semiconductor substrate 1202. In an example, one or more tunable capacitors described above (such as tunable capacitors 130, 132, 134, 132a, 134a, 130a, etc.) may be implemented as varactors 1204a, 1204b on the semiconductor substrate 1202. Although two such varactors 1204a, 1204b are illustrated in FIG. 12A, integrated circuit 1200 may include any other number of such varactors as well.

Integrated circuit 1200 comprises a plurality of metallization layers 1205. Metallization layers 1205 may be used to implement one or more components of the tunable hybrid coupler. For example, metallization layers 1205 comprise one or more metal layers 1208 in which one or more capacitors of the tunable hybrid coupler can be formed. In an example, metallization layers 1205 comprise one or more metal layers 1216 that form a ground plane of the tunable hybrid coupler. In an example, metallization layers 1205 comprise one or more metal layers 1220 in which one or more conductors of the tunable hybrid coupler, such as Z_{low} 108, Z_{low} 110, Z_{high} 112, and/or Z_{high} 116, or coils of 180, 182, 184, and 186, can be formed. Thus, at least part of the tunable hybrid coupler is in the metallization layers 1205 of the packaged integrated circuit 1200.

FIG. 12B is a schematic of a printed circuit board 1250 on or within which at least a part of a tunable hybrid coupler is implemented, in accordance with at least one example. The printed circuit board 1250 comprises a substrate 1252. In an example, one or more tunable capacitors described above (such as tunable capacitors 130, 132, 134, 132a, 134a, 130a, etc.) may be implemented as varactors 1254a, 1254b on the substrate 1252. Although two such varactors 1254a, 1254b are illustrated in FIG. 12B, any other number of such varactors may also be possible.

One or more of the tunable hybrid couplers may be on and/or embedded within substrate 1252 of printed circuit board 1250. For example, a ground plane 1258 is within (or on) substrate 1252. In an example, one or more metal planes 1262 may be on and/or embedded within substrate 1252. In an example, one or more metal planes 1262 may be used to implement one or more conductive lines of the tunable hybrid coupler, such as Z_{low} 108, Z_{low} 110, Z_{high} 112, and/or Z_{high} 116, or coils of 180, 182, 184, and 186.

FIG. 12C is a schematic of a packaging arrangement for a tunable hybrid coupler, in accordance with at least one example. The packaging arrangement comprises a die 1209 including one or more tunable capacitors described above (such as tunable capacitors or varactors 130, 132, 134, 132a, 134a, 130a, etc.), such as tunable capacitors or varactors 1254a, 1254b. Although two such varactors 1254a, 1254b are illustrated in FIG. 12C, any other number of such varactors may also be possible.

One or more of conductive transmission lines may be on and/or embedded within package substrate 1259. For example, a ground plane 1261 is within (or on) package substrate 1259. In an example, one or more metal planes 1263 may be on and/or embedded within package substrate 1259. In an example, one or more metal planes 1263 may be used to implement one or more conductive lines of the tunable hybrid coupler, such as Z_{low} 108, Z_{low} 110, Z_{high} 112, and/or Z_{high} 116, or coils of 180, 182, 184, and 186.

Die 1209 may be coupled through a plurality of bumps or solder balls 1271 to the package substrate 1259, as illustrated in FIG. 12C. However, in another example, die 1209 may be wire bounded to the package substrate 1259.

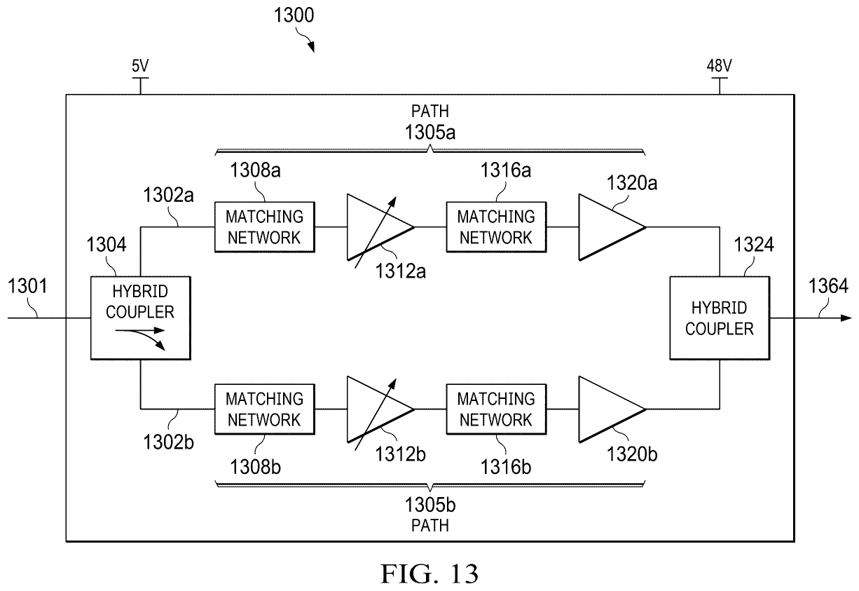

FIG. 13 is a schematic of a system 1300 employing one or more tunable hybrid couplers 1304, 1324, in accordance with at least one example. The system 1300 may be used to amplify an input RF signal 1301. Note that input RF signal 1301 may be received from an amplifier circuit (not illustrated in FIG. 13).

Input RF signal 1301 is received by a tunable hybrid coupler 1304, which splits input RF signal 1301 into two output signals 1302a and 1302b at two output terminals of tunable hybrid coupler 1304 (such as output terminals 102, 104 described above). A phase offset and/or an amplitude offset between output signals 1302a and 1302b are tunable, e.g., by appropriately tuning tunable hybrid coupler 1304, as described above.

Signal 1302a is transmitted through a first RF path 1305a comprising a matching network 1308a, an amplifier circuit 1312a (such as a class AB amplifier), another matching network 1316a, and another amplifier circuit 1320a (such as a class AB and/or class B amplifier), and provided as an input signal to another tunable hybrid coupler 1324.

Signal 1302b is transmitted through a second RF path 1305b comprising a matching network 1308b, an amplifier circuit 1312b (such as a class AB amplifier), another matching network 1316b, and another amplifier circuit 1320b (such as a class C amplifier), and provided as another input signal to tunable hybrid coupler 1324.

In an example, a phase and/or an amplitude of tunable hybrid coupler 1304 may be tuned, e.g., to account for possible phase mismatch and/or amplitude mismatch between RF paths 1305a and 1305b.

Tunable hybrid coupler 1324 receives the signals 1302a and 1302b (e.g., after these signals are processed by the first and second RF paths), and combines the signals to generate a combined output signal 1364, which may be an amplified version of the RF input signal 1301. Note that output RF signal 1364 may be processed by another amplifier circuit (not illustrated in FIG. 13). In an example, tunable hybrid coupler 1324 has two input terminals (e.g., terminals 102, 104), one output terminal (e.g., terminal 101), and an isolation terminal (e.g., terminal 103). Thus, role of the terminals 101, 102, 103, 104 depicted in FIG. 1B is reversed for tunable hybrid coupler 1324 of FIG. 13.

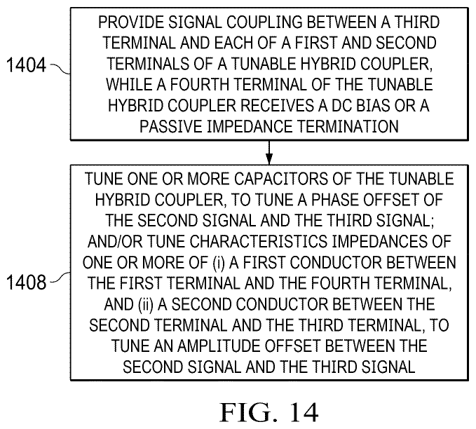

FIG. 14 is a flowchart 1400 of a method of operating a tunable hybrid coupler, in accordance with at least one example. While various blocks are shown in a particular order, the order may be modified. For example, some blocks may be performed before others, while some blocks may be performed simultaneously.

At block 1404, a tunable hybrid coupler provides signal coupling between a third terminal (e.g., terminal 101) and each of a first and second terminals (e.g., terminals 102 and 104), while a fourth terminal of the tunable hybrid coupler receives a DC bias or a passive impedance termination.

At block 1408, one or more capacitors (such as one or more of capacitors 130, 132, 134) of the tunable hybrid coupler are tuned, to tune a phase offset of the second signal and the third signal.

Additionally or alternatively, characteristics impedances of one or more of the following are tuned: (i) a first conductor between the first terminal and the fourth terminal, and (ii) a second conductor between the second terminal and the third terminal. Such tuning of the characteristics impedances results in tuning of an amplitude phase offset between the second signal and the third signal.

The following are additional examples provided in view of the above-described implementations. Here, one or more features of example, in isolation or in combination, can be combined with one or more features of one or more other examples to form further examples also falling within the scope of the disclosure. As such, one implementation can be combined with one or more other implementations without changing the scope of disclosure.

Example 1. An apparatus comprising: a hybrid coupler circuit having a first terminal, a second terminal, a third terminal, and a fourth terminal, and one or more control inputs, the hybrid coupler circuit coupled to a bias network or a passive impedance termination and configurable to: provide signal coupling between the third terminal and each of first and second terminals; and responsive to one or more control signals at the one or more control inputs, configure at least one of a phase offset or an amplitude offset between signals at the first and second terminals.

Example 2. The apparatus of example 1, wherein the hybrid coupler includes: a first conductor coupled between the first and second terminals; a second conductor coupled between the third and fourth terminals; a third conductor coupled between the first and third terminals; and a fourth conductor coupled between the second and fourth terminals.

Example 3. The apparatus of any one of examples 1-2, wherein the hybrid coupler includes: a first winding coupled between the first terminal and the third terminal; and a second winding coupled between the second terminal and the fourth terminal, the second winding being magnetically coupled to the first winding.

Example 4. The apparatus of any one of examples 1-3, wherein: the hybrid coupler includes a first capacitor coupled between the first terminal and a ground and a second capacitor coupled between the second terminal and the ground; the first capacitor has a first capacitance configurable responsive to a first control signal of the one or more control signals; the second capacitor has a second capacitance configurable responsive to the first control signal; and the phase offset is configurable responsive to the first and second capacitances being configured responsive to the first control signal.

Example 5. The apparatus of example 4, wherein the first and second capacitances are configured differentially responsive to the first control signal.

Example 6. The apparatus of example 5, further comprising a third capacitor coupled to the third terminal, wherein the third capacitor has a third capacitance configurable responsive to a second control signal of the one or more control signals, and the phase offset is configurable responsive to the third capacitance being configured responsive to the second control signal.

Example 7. The apparatus of any one of examples 4-6, wherein each of the first and second capacitors includes at least one of: a varactor, or a set of switch capacitors and a set of switches.

Example 8. The apparatus of any one of examples 2-7, wherein: the first conductor has a first characteristic impedance configurable responsive to a first control signal of the one or more control signals; the second conductor has a second characteristic impedance configurable responsive to the first control signal; and the amplitude offset is configurable responsive to the first and second characteristic impedances being configured responsive to the first second control signal of the one or more control signals.

Example 9. The apparatus of example 8, further comprising: a set of first capacitors coupled between the first conductor and ground, the set of first capacitors being distributed along the first conductor, and each of the first capacitors having a first capacitance configurable responsive to the first control signal; and a set of second capacitors coupled between the second conductor and the ground, the set of second capacitors being distributed along the second conductor, each of the second capacitors having a second capacitance configurable responsive to the first control signal.

Example 10. The apparatus of any one of examples 3-9, further comprising: a first capacitor coupled between the first terminal and ground; a second capacitor coupled between the second terminal and the ground; a third capacitor coupled between the third terminal and the ground; and a fourth capacitor coupled between the fourth terminal and the ground, wherein each of one or more of the first, second, third, and fourth capacitors has a capacitance configurable responsive to a first control signal of the one or more control signals.

Example 11. The apparatus of any one of examples 1-10, further comprising a first amplifier circuit coupled to the first terminal and a second amplifier circuit coupled to the second terminal, the first amplifier circuit configurable as a class AB or a class B amplifier, and the second amplifier circuit configurable as a class C amplifier.

Example 12. The apparatus of example 11, wherein a first input of the first amplifier circuit is coupled to the first terminal, and a second input of the second amplifier circuit is coupled to the second terminal.

Example 13. The apparatus of any one of examples 11-12, wherein a first output of the first amplifier circuit is coupled to the first terminal, and a second output of the second amplifier circuit is coupled to the second terminal.

Example 14. The apparatus of any one of examples 1-13, wherein at least part of the hybrid coupler circuit is in a metallization structure of a packaged integrated circuit.

Example 15. The apparatus of any one of examples 1-14, wherein at least part of the hybrid coupler circuit is in a package substrate or a printed circuit board.

Example 16. An apparatus comprising: a first amplifier circuit; a second amplifier circuit; a hybrid coupler circuit having a first terminal, a second terminal, a third terminal, and a fourth terminal, the first terminal coupled to the first amplifier circuit, the second terminal coupled to the second amplifier circuit, in which the hybrid coupler circuit has at least one of a configurable amplitude offset or a configurable phase offset between signals at the first and second terminals, and the third terminal coupled to an input or an output of a third amplifier circuit; and a bias network or a passive impedance termination coupled to the fourth terminal.

Example 17. The apparatus of example 16, wherein the hybrid coupler includes: a first conductor coupled between the first and second terminals; a second conductor coupled between the third and fourth terminals; a third conductor coupled between the first and third terminals; and a fourth conductor coupled between the second and fourth terminals.

Example 18. The apparatus of example 17, wherein: the hybrid coupler includes (i) a first capacitor coupled between the first terminal and a ground and (ii) a second capacitor coupled between the second terminal and the ground; the first capacitor has a first capacitance configurable responsive to a control signal; the second capacitor has a second capacitance configurable responsive to the control signal; and the phase offset is configurable responsive to the first and second capacitances being configured responsive to the control signal.

Example 19. The apparatus of any one of examples 17-18, wherein: the first conductor has a first characteristic impedance configurable responsive to a control signal; the second conductor has a second characteristic impedance configurable responsive to the control signal; and the amplitude offset is configurable responsive to the first and second conductors being configured responsive to the control signal.

Example 20. An integrated circuit comprising: a first amplifier circuit; a second amplifier circuit; and a hybrid coupler circuit having a first terminal, a second terminal, a third terminal, a fourth terminal, the first terminal coupled to the first amplifier circuit, the second terminal coupled to the second amplifier circuit, in which the hybrid coupler circuit has at least one of a configurable amplitude offset or a configurable phase offset between the first and second terminals, wherein a conductor coupled between the first and second terminals is in a metallization structure of the integrated circuit.

Example 21. The integrated circuit of example 20, wherein the first terminal is coupled to an input of the first amplifier circuit, and the second terminal is coupled to an input of the second amplifier.

Example 22. The integrated circuit of example 21, wherein the hybrid coupler circuit is a first hybrid coupler circuit, and the integrated circuit further comprises: a second hybrid coupler circuit having a fifth terminal, a sixth terminal, a seventh terminal, and an eighth terminal, the fifth terminal coupled to an output of the first amplifier, the sixth terminal coupled to an output of the second amplifier, and the second hybrid coupler having at least one of a configurable amplitude offset or a configurable phase offset between the fifth and sixth terminals; and a third amplifier having an input coupled to the seventh terminal of the second hybrid coupler circuit.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In the description and in the claims, the terms “including” and “having” and variants thereof are intended to be inclusive in a manner similar to the term “comprising” unless otherwise noted. In addition, the terms “couple,” “coupled,” or “couples” means an indirect or direct electrical or mechanical connection.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics, or semiconductor component.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN), or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component, may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means being within +/−10 percent of that parameter or, if the parameter is zero, a reasonable range of values around zero.

What is claimed is:

1. An apparatus comprising:
a hybrid coupler circuit having a first terminal, a second terminal, a third terminal, and a fourth terminal, and one or more control inputs, the hybrid coupler circuit coupled to a bias network or a passive impedance termination and configurable to:
provide signal coupling between the third terminal and each of first and second terminals; and
responsive to one or more control signals at the one or more control inputs, configure at least one of a phase offset or an amplitude offset between signals at the first and second terminals.

2. The apparatus of claim 1, wherein the hybrid coupler includes:
a first conductor coupled between the first and second terminals;
a second conductor coupled between the third and fourth terminals;
a third conductor coupled between the first and third terminals; and
a fourth conductor coupled between the second and fourth terminals.

3. The apparatus of claim 1, wherein the hybrid coupler includes:
a first winding coupled between the first terminal and the third terminal; and
a second winding coupled between the second terminal and the fourth terminal, the second winding being magnetically coupled to the first winding.

4. The apparatus of claim 1, wherein:
the hybrid coupler includes a first capacitor coupled between the first terminal and a ground and a second capacitor coupled between the second terminal and the ground;
the first capacitor has a first capacitance configurable responsive to a first control signal of the one or more control signals;
the second capacitor has a second capacitance configurable responsive to the first control signal; and
the phase offset is configurable responsive to the first and second capacitances being configured responsive to the first control signal.

5. The apparatus of claim 4, wherein the first and second capacitances are configured differentially responsive to the first control signal.

6. The apparatus of claim 5, further comprising a third capacitor coupled to the third terminal, wherein the third capacitor has a third capacitance configurable responsive to a second control signal of the one or more control signals, and the phase offset is configurable responsive to the third capacitance being configured responsive to the second control signal.

7. The apparatus of claim 4, wherein each of the first and second capacitors includes at least one of: a varactor, or a set of switch capacitors and a set of switches.

8. The apparatus of claim 2, wherein:
the first conductor has a first characteristic impedance configurable responsive to a first control signal of the one or more control signals;
the second conductor has a second characteristic impedance configurable responsive to the first control signal; and
the amplitude offset is configurable responsive to the first and second characteristic impedances being configured responsive to the first second control signal of the one or more control signals.

9. The apparatus of claim 8, further comprising:
a set of first capacitors coupled between the first conductor and ground, the set of first capacitors being distributed along the first conductor, and each of the first capacitors having a first capacitance configurable responsive to the first control signal; and
a set of second capacitors coupled between the second conductor and the ground, the set of second capacitors being distributed along the second conductor, each of the second capacitors having a second capacitance configurable responsive to the first control signal.

10. The apparatus of claim 3, further comprising:
a first capacitor coupled between the first terminal and ground;
a second capacitor coupled between the second terminal and the ground;
a third capacitor coupled between the third terminal and the ground; and
a fourth capacitor coupled between the fourth terminal and the ground,
wherein each of one or more of the first, second, third, and fourth capacitors has a capacitance configurable responsive to a first control signal of the one or more control signals.

11. The apparatus of claim 1, further comprising a first amplifier circuit coupled to the first terminal and a second amplifier circuit coupled to the second terminal, the first amplifier circuit configurable as a class AB or a class B amplifier, and the second amplifier circuit configurable as a class C amplifier.

12. The apparatus of claim 11, wherein a first input of the first amplifier circuit is coupled to the first terminal, and a second input of the second amplifier circuit is coupled to the second terminal.

13. The apparatus of claim 11, wherein a first output of the first amplifier circuit is coupled to the first terminal, and a second output of the second amplifier circuit is coupled to the second terminal.

14. The apparatus of claim 1, wherein at least part of the hybrid coupler circuit is in a metallization structure of a packaged integrated circuit.

15. The apparatus of claim 1, wherein at least part of the hybrid coupler circuit is in a package substrate or a printed circuit board.

16. An apparatus comprising:
a first amplifier circuit;
a second amplifier circuit;
a hybrid coupler circuit having a first terminal, a second terminal, a third terminal, and a fourth terminal, the first terminal coupled to the first amplifier circuit, the second terminal coupled to the second amplifier circuit, in which the hybrid coupler circuit has at least one of a configurable amplitude offset or a configurable phase offset between signals at the first and second terminals, and the third terminal coupled to an input or an output of a third amplifier circuit; and
a bias network or a passive impedance termination coupled to the fourth terminal.

17. The apparatus of claim 16, wherein the hybrid coupler includes:
a first conductor coupled between the first and second terminals;
a second conductor coupled between the third and fourth terminals;
a third conductor coupled between the first and third terminals; and
a fourth conductor coupled between the second and fourth terminals.

18. The apparatus of claim 17, wherein:
the hybrid coupler includes (i) a first capacitor coupled between the first terminal and a ground and (ii) a second capacitor coupled between the second terminal and the ground;
the first capacitor has a first capacitance configurable responsive to a control signal;
the second capacitor has a second capacitance configurable responsive to the control signal; and
the phase offset is configurable responsive to the first and second capacitances being configured responsive to the control signal.

19. The apparatus of claim 17, wherein:
the first conductor has a first characteristic impedance configurable responsive to a control signal;
the second conductor has a second characteristic impedance configurable responsive to the control signal; and
the amplitude offset is configurable responsive to the first and second conductors being configured responsive to the control signal.

20. An integrated circuit comprising:
a first amplifier circuit;
a second amplifier circuit; and
a hybrid coupler circuit having a first terminal, a second terminal, a third terminal, a fourth terminal, the first terminal coupled to the first amplifier circuit, the second terminal coupled to the second amplifier circuit, in which the hybrid coupler circuit has at least one of a configurable amplitude offset or a configurable phase offset between the first and second terminals,
wherein a conductor coupled between the first and second terminals is in a metallization structure of the integrated circuit.

21. The integrated circuit of claim 20, wherein the first terminal is coupled to an input of the first amplifier circuit, and the second terminal is coupled to an input of the second amplifier.

22. The integrated circuit of claim 21, wherein the hybrid coupler circuit is a first hybrid coupler circuit, and the integrated circuit further comprises:
a second hybrid coupler circuit having a fifth terminal, a sixth terminal, a seventh terminal, and an eighth terminal, the fifth terminal coupled to an output of the first amplifier, the sixth terminal coupled to an output of the second amplifier, and the second hybrid coupler having at least one of a configurable amplitude offset or a configurable phase offset between the fifth and sixth terminals; and
a third amplifier having an input coupled to the seventh terminal of the second hybrid coupler circuit.
